(19) United States
(12) Patent Application Publication
(10) Pub. No.: US 2024/0087919 A1
(43) Pub. Date: Mar. 14, 2024

(54) SUBSTRATE PROCESSING APPARATUS AND PROTECTIVE LAYER FORMING METHOD

(71) Applicant: Ebara Corporation, Tokyo (JP)

(72) Inventor: Jumpei FUJIKATA, Tokyo (JP)

(73) Assignee: Ebara Corporation, Tokyo (JP)

(21) Appl. No.: 18/458,866

(22) Filed: Aug. 30, 2023

(30) Foreign Application Priority Data
Sep. 12, 2022 (JP) 2022-144843

(51) Int. Cl. H01L 21/67; H01L 21/304

(52) U.S. Cl. CPC H01L 21/67092; H01L 21/304; H01L 21/67173; H01L 21/67219; H01L 21/67253; H01L 2221/6834

(57) ABSTRACT

The present disclosure provides a substrate processing apparatus and a protective layer forming method that can protect surfaces of metal regions after a polishing process from oxidation and adhesion of cutting chips and particles caused in a process after polishing. The substrate processing apparatus according to the present disclosure includes a polishing device for polishing a semiconductor substrate, a protective layer forming device for forming a protective layer on a surface of the substrate using a silane coupling agent or a resin protective film agent, and a control device. The control device controls the polishing device and the protective layer forming device such that the protective layer forming device forms the protective layer on the substrate after the polishing device finishes polishing the substrate.

### CROSS REFERENCE TO RELATED APPLICATION

This application is based upon and claims benefits of priorities from Japanese Patent Application No. 2022-144843 filed on Sep. 12, 2022, the entire contents of which are incorporated herein by reference.

### TECHNICAL FIELD

The present invention relates to a substrate processing apparatus and a protective layer forming method.

### BACKGROUND ART

A technique for bonding semiconductor substrates has been used in the electronics field. For example, as a Wafer on Wafer (WoW) technique for stacking a plurality of wafers, PTL 1 and PTL 2 disclose such a technique for bonding semiconductor substrates. As Chip on Wafer (CoW) technique for stacking divided chips on a wafer, PTL 3 discloses such a technique for bonding semiconductor substrates.

A method of bonding substrates including bonding surfaces including metal regions disclosed by PTL 1 includes a step of polishing the bonding surfaces including the metal regions, a step of performing surface activation treatment and performing hydrophilic treatment on the polished bonding surfaces, a step of pasting together the bonding surfaces of the substrates to form a substrate bonded body, and a step of heating the substrate bonded body to solid-phase diffuse the metal.

A method of bonding two substrates disclosed by PTL 2 and PTL 3 includes a hydrophilic treatment process for hydrophilizing at least one of bonding surfaces of the two substrates and a bonding process for bonding the two substrates after the hydrophilic treatment process.

It is disclosed that cutting chips and particles adhere to a chip surface in a wafer dicing process and a process after the wafer dicing process disclosed by PTL 4 and PTL 5.

### CITATION LIST

### Patent Literature

PTL 1: Japanese Patent No. 6425317
PTL 2: Japanese Patent No. 6388272
PTL 3: Japanese Patent No. 6337400
PTL 4: Japanese Patent No. 3154194
PTL 5: Japanese Patent Application Laid-Open No. 2021-190557

### SUMMARY OF INVENTION

### Technical Problem

As explained above, the substrate bonding method of PTL 1 includes a polishing process (the polishing step) and a bonding process (the step of performing the surface activation treatment and the hydrophilic treatment to the step of sold-phase diffusing metal). When bonding of the substrates is performed, the substrates after the polishing process are sometimes temporarily stored according to necessity. In such a case, if a time from the polishing process to the bonding process is long, it is likely that the metal regions react with the oxygen in the air and oxide films are formed on the surfaces of the metal regions. When the oxide films are formed on the surfaces of the metal regions, a deficiency such as a connection failure could occur in connection of the metal regions between the two substrates to be bonded.

In the method of bonding the substrates of PTL 2, the same problem as the problem of the method of PTL 1 could occur when the substrates are bonded after a long time elapsed from the polishing process.

The CoW technique for stacking a chip on a wafer includes a dicing process for dividing a polished wafer into chips. In the dicing process disclosed in PTL 4, a problem could occur in that cutting powder and particles caused in cutting during the dicing process adhere to bonding surfaces of chips.

Because of these reasons, there have been demanded an apparatus and a method that can protect the surfaces of the metal regions after the polishing process from oxidation and protect the surfaces of the metal regions from adhesion of cutting chips and particles.

Therefore, an object of the present disclosure is to provide a substrate processing apparatus and a protective layer forming method that can protect surfaces of metal regions after a polishing process from oxidation and adhesion of cutting chips and particles caused in a process after polishing.

### Solution to Problem

A substrate processing apparatus according to an embodiment includes: a polishing device for polishing a semiconductor substrate; a protective layer forming device for forming a protective layer on a surface of the substrate using a silane coupling agent or a resin protective film agent; and a control device. The control device controls the polishing device and the protective layer forming device such that the protective layer forming device forms the protective layer on the substrate after the polishing device finishes polishing the substrate.

A protective layer forming method according to an embodiment includes: a first step of polishing a semiconductor substrate; and a second step of forming a protective layer on a surface of the substrate using a silane coupling agent or a resin protective film agent after the first step.

### BRIEF DESCRIPTION OF DRAWINGS

FIG. 1 is a plan view showing an overall configuration of a substrate processing apparatus according to an embodiment of the present disclosure;

FIG. 2 is a perspective view schematically showing a polishing device shown in FIG. 1;

FIG. 3 is a perspective view schematically showing a buff cleaning device shown in FIG. 1;

FIG. 4 is a diagram showing a schematic configuration of a coating device shown in FIG. 1;

FIG. 5 is a diagram showing a schematic configuration of a buff cleaning device according to another embodiment of the present disclosure;

FIG. 6 is a block diagram showing a schematic configuration of a bake device shown in FIG. 1;

FIG. 7 is a plan view showing an overall configuration of a substrate processing apparatus according to another embodiment of the present disclosure;

FIG. 8 is a block diagram schematically showing a protective layer forming device shown in FIG. 7;

FIG. 9 is a plan view showing an overall configuration of a substrate processing apparatus according to another embodiment of the present disclosure;

FIG. 10 is a plan view showing an overall configuration of a substrate processing apparatus according to another embodiment of the present disclosure; and

FIG. 11 is a perspective view schematically showing a bonding device shown in FIG. 10.

### DESCRIPTION OF EMBODIMENTS

Embodiments of the present invention are explained below with reference to the drawings. In the drawings referred to below, the same or equivalent components are denoted by the same reference numerals and signs and redundant explanation of the components is omitted.

<Substrate Processing Apparatus 100A>

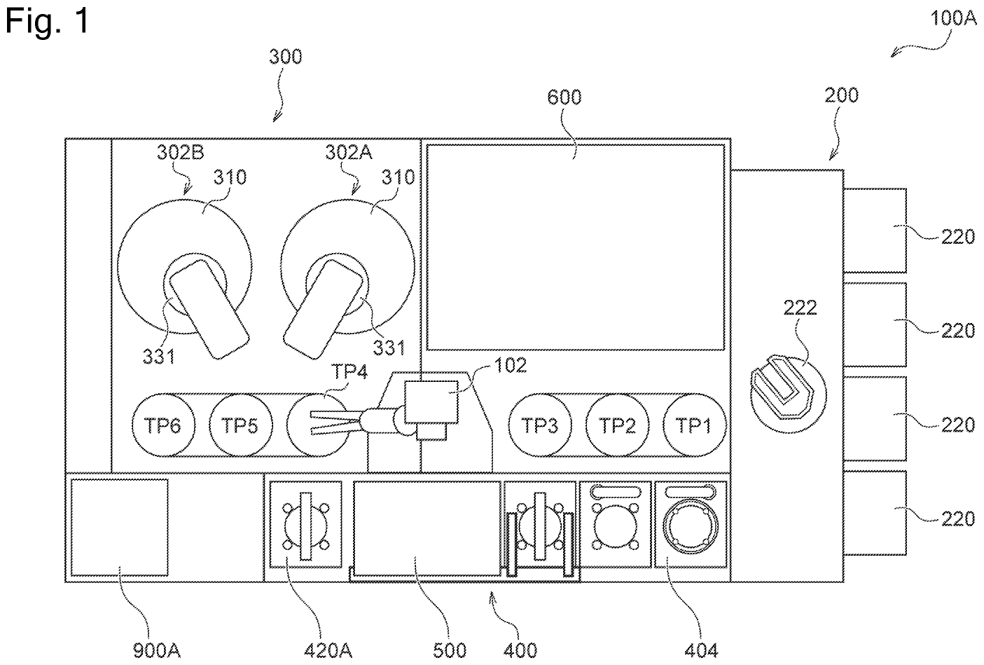

FIG. 1 is a plan view showing an overall configuration of a substrate processing apparatus 100A according to an embodiment of the present disclosure. The substrate processing apparatus 100A is an apparatus for performing processing on a semiconductor substrate W. In particular, the substrate processing apparatus 100A performs processing on the substrate W including an insulation region and a metal region of copper (Cu) or the like formed on the surface of the insulation region by a deposition method such as plating or vapor deposition. However, the substrate processing apparatus 100A may perform the processing on the substrate W including only the insulation region. Note that the semiconductor substrate W includes a wafer such as a silicon wafer, a glass wafer, or a quartz wafer. Referring to FIG. 1, the substrate processing apparatus 100A includes a load/unload module 200, a polishing module 300, a cleaning module 400, and a bake device 600. Further, the substrate processing apparatus 100A includes a control device 900A for controlling operations of the load/unload module 200, the polishing module 300, the cleaning module 400, and the bake device 600.

The load/unload module 200 performs processing for transferring the substrate W stored in a carrier, which can store a plurality of substrates W, into the substrate processing apparatus 100A and processing for storing the substrate W after being processed by the substrate processing apparatus 100A in the carrier from the substrate processing apparatus 100A. The polishing module 300 has a function of polishing the substrate W. The cleaning module 400 has a function of cleaning the polished substrate W. The bake device 600 has a function of heating the substrate W.

Further, the substrate processing apparatus 100A includes a transporter 102, a transfer device (not shown) that exchanges substrate W between a transfer robot 222 and the transporter 102, and a transfer device (not shown) for transferring the substrate W polished by the polishing module 300 to the cleaning module 400. Configurations of the modules and the devices of the substrate processing apparatus 100A are explained below.

<Load/Unload Module 200>

The load/unload module 200 includes two or more (four in the substrate processing apparatus 100A) front loaders 220 on which wafer cassettes for stocking a large number of substrates W are placed. The front loaders 220 are arrayed along the width direction (a direction perpendicular to the longitudinal direction) of the substrate processing apparatus 100A. The front loaders 220 are configured such that an open cassette, an SMIF (Standard Manufacturing Interface) pod, or a FOUP (Front Opening Unified Pod) can be loaded on the front loaders 220. The SMIF and the FOUP are closed containers that can keep an environment independent of an external space by storing wafer cassettes on the insides and covering the wafer cassettes with partition walls.

The load/unload module 200 includes the transfer robot 222 movable along the arrangement of the front loaders 220. The transfer robot 222 is configured to be able to access the substrates W loaded on the respective front loaders 220.

<Transporter 102>

As shown in FIG. 1, the transporter 102 is configured to be able to transfer the substrate W among six transfer positions (a first transfer position TP1, a second transfer position TP2, a third transfer position TP3, a fourth transfer position TP4, a fifth transfer position TP5, and a sixth transfer position TP6 in order from the load/unload module 200 side) in a direction in which a first polishing device 302A and a second polishing device 302B are arrayed.

<Polishing Module 300>

The polishing module 300 polishes (planarizes) the substrate W. The polishing module 300 includes the first polishing device (CMP device) 302A and the second polishing device (CMP device) 302B. The first polishing device 302A and the second polishing device 302B are devices for polishing the substrate W and are arrayed in the longitudinal direction of the substrate processing apparatus 100A. Since the first polishing device 302A and the second polishing device 302B have the same configuration, the first polishing device 302A and the second polishing device 302B are sometimes simply referred to as polishing device. In the following explanation, only the first polishing device 302A is explained in order to avoid redundancy of explanation.

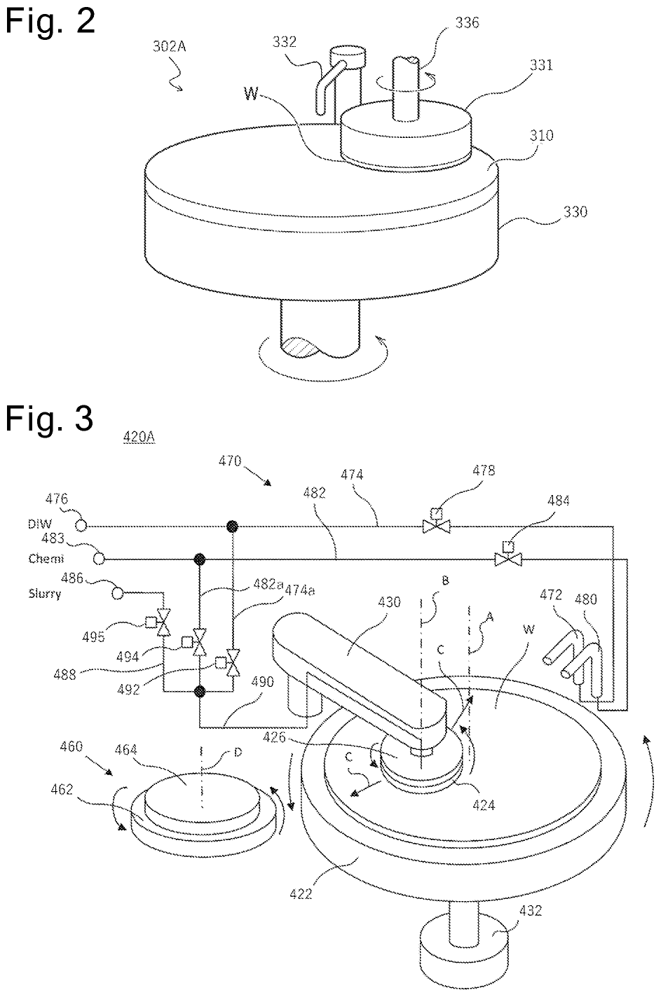

FIG. 2 is a perspective view schematically showing the first polishing device 302A. As shown in FIGS. 1 and 2, as an example, the first polishing device 302A includes a polishing pad 310 including a polishing surface, a polishing table 330, a top ring 331, a polishing liquid supply nozzle 332 (see FIG. 2), a dresser (not shown), and an atomizer (not shown). The top ring 331 has a function of holding the substrate W and can press the substrate W against the polishing pad 310. Consequently, the substrate W is pressed against the polishing pad 310 and polished. The polishing liquid supply nozzle 332 (see FIG. 29) has a function of supplying polishing liquid and dressing liquid (for example, pure water) to the polishing pad 310. The dresser has a function of performing dressing for the polishing surface of the polishing pad 310. The atomizer has a function of jetting mixed fluid of liquid (for example, pure water) and gas (for example, nitrogen gas) or the liquid (for example, the pure water) and removing slurry and a polishing product on the polishing surface and a pad residue due to the dressing.

As shown in FIG. 2, the top ring 331 is supported by a top ring shaft 336. The polishing pad 310 is attached to the upper surface of the polishing table 330. The upper surface of the polishing pad 310 forms the polishing surface for polishing the substrate W. The top ring 331 and the polishing table 330 are configured to be able to rotate around the axis thereof as indicated by an arrow. The substrate W is held on the lower surface of the top ring 331 by vacuum suction. At the time of polishing, in a state in which the polishing liquid is supplied from the polishing liquid supply nozzle 332 to the polishing surface of the polishing pad 310, the substrate W, which is a polishing target, is pressed against the polishing surface of the polishing pad 310 by the top ring 331 and polished.

The top ring 331 of the first polishing device 302A is moved between a polishing position and the fourth transfer position TP4 by a swing motion of the top ring head (see FIG. 1). Therefore, the substrate W is passed to the top ring 331 in the fourth transfer position TP4. Similarly, the top ring 331 of the second polishing device 302B moves between the polishing position and the fifth transfer position TP5. The substrate W is passed to the top ring 331 in the fifth transfer position TP5.

<Cleaning Module 400>

Referring to FIG. 1, as an example, the cleaning module 400 includes a buff cleaning device 420A, a coating device 500, and a drying device 404. Further, the cleaning module 400 includes a transfer device (not shown) for transferring the substrate W among the buff cleaning device 420A, the coating device 500, and the drying device 404. The cleaning module 400 may include, according to necessity, a known cleaning device for cleaning the substrate W. The components of the cleaning module 400 are explained below.

<Drying Device 404>

The drying device 404 includes a stage that rotates the substrate W at high speed with a known method. The drying device 404 includes a filter and may be configured to be able to supply clean air to the substrate W with a known method. The drying device 404 can dry the substrate W by rotating the substrate W at high speed. At the same time, the drying device 404 can dry the substrate W in a short time by supplying the air to the substrate W.

<Buff Cleaning Device 420A>

FIG. 3 is a perspective view schematically showing the buff cleaning device 420A. As shown in FIG. 3, the buff cleaning device 420A includes a buff table 422 on which the substrate W is installed, a buff head 426 to which a buff pad 424 for performing treatment on a treatment surface of the substrate W is attached, an arm 430 that holds the buff head 426, a treatment liquid supply system 470 for supplying treatment liquid, and a conditioner 460 for performing conditioning (dressing) for the buff pad 424. The treatment liquid includes at least one of pure water, cleaning chemical liquid, and polishing liquid such as slurry. The buff pad 424 is formed by, for example, a foamed polyurethane-based hard pad, a suede-based soft pad, or sponge. A type of the buff pad 424 only has to be selected as appropriate for a material of a treatment target object or a state of a contaminant that should be removed. A groove shape such as a concentric circular groove, an XY groove, a swirl groove, or a radial groove may be applied to the surface of the buff pad 424. Further, at least one or more holes piercing through the buff pad 424 may be provided in the buff pad 424 to supply the treatment liquid through the holes. A sponge-like material through which the treatment liquid can penetrate such as PVA sponge may be used for the buff pad 424.

The buff table 422 includes a mechanism for sucking the substrate W and holds the substrate W. The buff table 422 is configured to be able to be rotated around a rotation axis A by a motor 432. The buff pad 424 is attached to a surface of the buff head 426 opposed to the substrate W. The buff head 426 is configured to be able to be rotated around a rotation axis B by a not-shown driving mechanism. The buff head 426 is configured to be able to press the buff pad 424 against the treatment surface of the substrate W. The arm 430 is moved by a motor 431 (see FIG. 5). As a result, the buff head 426 can move in the direction of an arrow C. The arm 432 is configured to be able to move the buff head 426 to a position where the buff pad 424 is opposed to the conditioner 460.

The conditioner 460 is configured to perform conditioning for the surface of the buff pad 424. The conditioner 460 includes a dress table 462 and a dresser 464 installed on the dress table 462. The dress table 462 can be rotated around a rotation axis D by a not-shown driving mechanism. The dresser 464 is formed by a diamond dresser in which diamond abrasive grains are disposed on a part of or the entire contact surface with the buff pad 424, a brush dresser in which brush bristles made of resin are disposed on a part or the entire contact surface with the buff pad 424, or a combination of the diamond dresser and the brush dresser.

When performing conditioning for the buff pad 424, the buff cleaning device 420A turns the arm 430 to a position where the buff pad 424 is opposed to the dresser 464. The buff cleaning device 420A performs the conditioning for the buff pad 424 by rotating the dress table 462 around the rotation axis D and rotating the buff head 426 and pressing the buff pad 424 against the dresser 464.

The treatment liquid supply system 470 includes a pure water nozzle 472 for supplying pure water to the treatment surface of the substrate W. The pure water nozzle 472 is connected to a pure water supply source 476 via a pure water pipe 474. An on-off valve 478 that can open and close the pure water pipe 474 is provided in the pure water pipe 474. The control device 900A can supply the pure water to the treatment surface of the substrate W at any timing by controlling opening and closing of the on-off valve 478.

The treatment liquid supply system 470 includes a chemical liquid nozzle 480 for supplying chemical liquid (Chemi) to the treatment surface of the substrate W. The chemical liquid nozzle 480 is connected to a chemical liquid supply source 483 via a chemical liquid pipe 482. In the chemical liquid pipe 482, an on-off valve 484 that can open and close the chemical liquid pipe 482 is provided. The control device 900A can supply the chemical liquid to the treatment surface of the substrate W at any timing by controlling opening and closing of the on-off valve 484.

Further, the buff cleaning device 420A is configured to be able to selectively supply polishing liquid such as pure water, chemical liquid, or slurry to the treatment surface of the substrate W via the arm 430, the buff head 426, and the buff pad 424.

That is, a branch pure water pipe 474a branches from between the pure water supply source 476 and the on-off valve 478 in the pure water pipe 474. A branch chemical liquid pipe 482a branches from between the chemical liquid supply source 483 and the on-off valve 484 in the chemical liquid pipe 482. The branch pure water pipe 474a, the branch chemical liquid pipe 482a, and a polishing liquid pipe 488 connected to a polishing liquid supply source 486 merge into a liquid supply pipe 490. In the branch pure water pipe 474a, an on-off valve 492 that can open and close the branch pure water pipe 474a is provided. In the branch chemical liquid pipe 482a, an on-off valve 494 that can open and close the branch chemical liquid pipe 482a is provided. In the polishing liquid pipe 488, an on-off valve 495 that can open and close the polishing liquid pipe 488 is provided.

A first end portion of the liquid supply pipe 490 is connected to pipes of three systems, that is, the branch pure water pipe 474a, the branch chemical liquid pipe 482a, and the polishing liquid pipe 488. The liquid supply pipe 490 extends through the inside of the arm 430, the center of the buff head 426, and the center of the buff pad 424. A second end portion of the liquid supply pipe 490 is opened toward the treatment surface of the substrate W. The control device 900A can supply any one of polishing liquids such as pure water, chemical liquid, and slurry or mixed liquid of any combination of the pure water, the chemical liquid, slurry, and the like to the treatment surface of the substrate W at any timing by controlling opening and closing of the on-off valve 492, the on-off valve 494, and the on-off valve 495.

The buff cleaning device 420A can perform buff cleaning on the substrate W by supplying the treatment liquid to the substrate W via the liquid supply pipe 490 and rotating the buff table 422 around the rotation axis A, pressing the buff pad 424 against the treatment surface of the substrate W, and swinging the buff head 426 in the arrow C direction while rotating the buff head 426 around the rotation axis B.

<Coating Device 500>

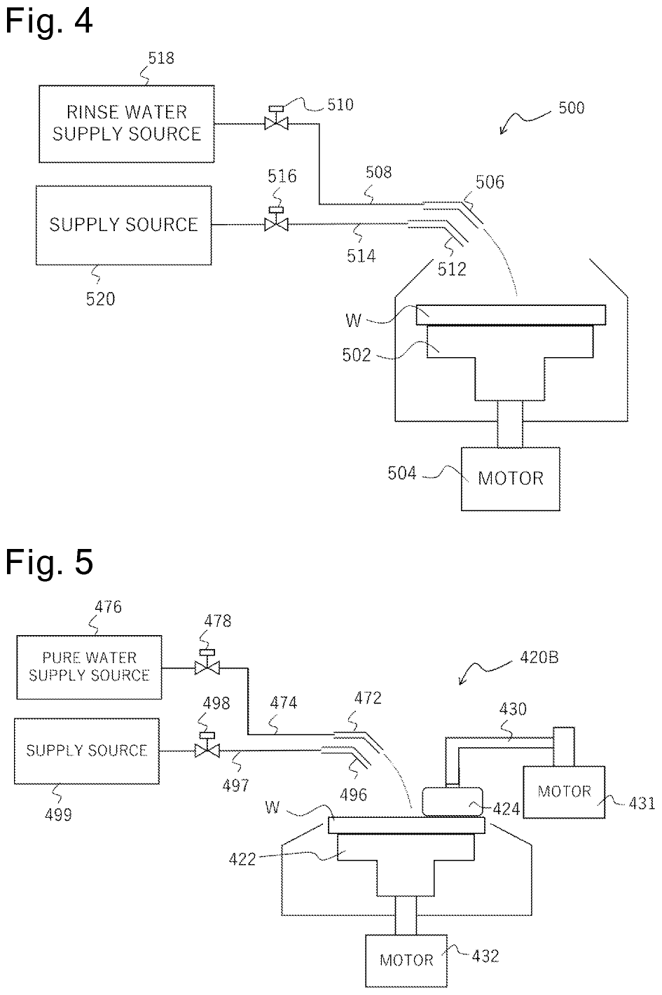

FIG. 4 is a diagram showing a schematic configuration of the coating device 500. The coating device 500 is a device for applying a silane coupling agent or a resin protective film agent to the substrate W. Note that the coating device 500 and the bake device 600 are included in a protective layer forming device. Referring to FIG. 4, the coating device 500 includes a table 502 for holding the substrate W, a motor 504 for rotating the table 502, a rinse water nozzle 506, a rinse water pipe 508, an on-off valve 510, a nozzle 512, a pipe 514, and an on-off valve 516.

The rinse water nozzle 506 is connected to a rinse water supply source 518 via the rinse water pipe 508. In the rinse water pipe 508, an on-off valve 510 that can open and close the rinse water pipe 508 is provided. The control device 900A can supply rinse water (for example, pure water) to the treatment surface of the substrate W at any timing by controlling opening and closing of the on-off valve 510.

The nozzle 512 is connected to a supply source 520 via the pipe 514. The supply source 520 is configured to be able to supply the silane coupling agent or the resin protective film agent. In the pipe 514, the on-off valve 516 that can open and close the pipe 514 is provided. The control device 900A can supply the silane coupling agent or the resin protective film agent to the treatment surface of the substrate W at any timing by controlling opening and closing of the on-off valve 516. Note that the silane coupling agent supplied to the substrate W is not particularly limited but is preferably a coupling agent having a thiol group. The resin protective film agent is not particularly limited but is preferably an agent including water soluble resin such as polyvinyl alcohol or polyethylene glycol as a base material.

In order to minimize formation of an oxide film on the surface of the metal region, it is preferable to minimize a time in which the substrate W is in contact with the oxygen in the air after drying. Usually, since drying starts from the center of the substrate W in drying by spin rotation after rinse, when the substrate W is dried to the outer circumferential portion of the substrate W, a difference occurs in times after the drying between the center and the outer circumferential portion. Therefore, it is possible to apply the silane coupling agent or the resin protective film agent to the entire region of the substrate W immediately after the drying of the substrate W by controlling opening and closing of the on-off valve 510 to stop the rinse water and controlling opening and closing of the on-off valve 516 to supply the silane coupling agent or the resin protective film agent to the center immediately after being dried by the spin rotation.

In the coating device 500, the control device 900A is configured to control the on-off valve 516 to cause the nozzle 512 to supply the silane coupling agent or the resin protective film agent to the substrate W after the drying of the center of the substrate W and before the drying of the outer circumferential portion of the substrate W. Consequently, the silane coupling agent or the resin protective film agent is applied to the substrate W immediately after the substrate W is dried. As a result, the substrate processing apparatus 100A can minimize formation of an oxide film on the surface of the metal region of the substrate W.

<Buff Cleaning Device 420B>

As explained above, the substrate processing apparatus 100A includes the coating device 500. However, instead of the substrate processing apparatus 100A including the coating device 500, a buff polishing device may have the function of the coating device 500 as well. That is, the buff polishing device may have a function of supplying the silane coupling agent or the resin protective film agent to the substrate W. Such a buff polishing device is called coating device as well. FIG. 5 is a diagram showing a schematic configuration of a buff cleaning device 420B according to another embodiment of the present disclosure. The buff cleaning device 420B has a function of supplying the silane coupling agent or the resin protective film agent to the substrate W. Referring to FIG. 5, the buff cleaning device 420B includes a nozzle 496, a pipe 497, and an on-off valve 498.

The nozzle 496 is connected to a supply source 499 via the pipe 497. The supply source 499 is configured to be able to supply the silane coupling agent or the resin protective film agent. In the pipe 497, the on-off valve 498 that can open and close the pipe 497 is provided. The control device 900A can supply the silane coupling agent or the resin protective film agent to the treatment surface of the substrate W at any timing by controlling opening and closing of the on-off valve 498. Note that the buff cleaning device 420B may further include the components included in the buff cleaning device 420A.

As explained above, the coating device 500 and the buff cleaning device 420B are explained as a device for applying the silane coupling agent or the resin protective film agent to the substrate W. However, the substrate processing apparatus 100A may include, instead of the coating device 500 and the buff cleaning device 420B, any coating device that can apply the silane coupling agent or the resin protective film agent to the substrate W. For example, the substrate processing apparatus 100A may include a coating device including a tank that stores the silane coupling agent or the resin protective film agent. In the case of such a coating device, the substrate W is put in the tank that stores the silane coupling agent or the resin protective film agent. The silane coupling agent or the resin protective film agent is applied to the substrate W.

<Bake Device 600>

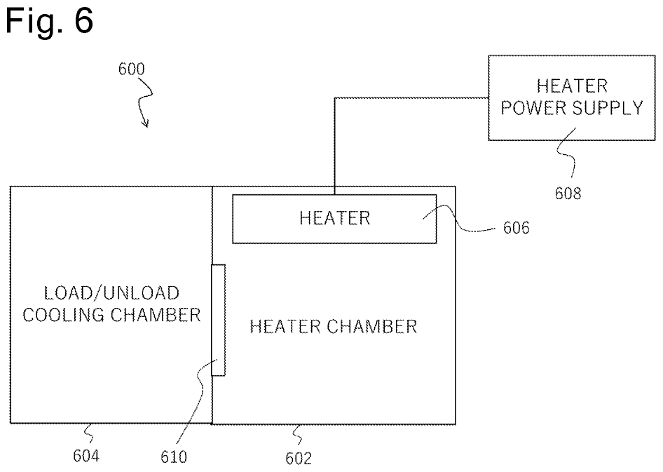

Subsequently, FIG. 6 is referred to. FIG. 6 is a block diagram showing a schematic configuration of the bake device 600. As shown in FIG. 6, the bake device 600 includes a heater chamber 602, a load/unload cooling chamber 604, a heater 606, a heater power supply 608, and a shutter 610.

The heater chamber 602 and the load/unload cooling chamber 604 are configured to be able to store a plurality of substrates W. The heater 606 is configured to heat the inside of the heater chamber 602 when electric power is supplied from the heater power supply 608. The shutter 610 is provided in a passage between the heater chamber 602 and the load/unload cooling chamber 604. The heater chamber 602 is configured to be insulated when the shutter 610 is closed.

<Control Device 900A>

The control device 900A is configured to, after the second polishing device 302B finishes polishing the substrate W, control the second polishing device 302B, the coating device 500, and the bake device 600 such that the coating device 500 and the bake device 600 form a protective layer on the substrate W with a method explained below.

<Operation of the Substrate Processing Apparatus 100A>

Subsequently, an example of an operation of the substrate processing apparatus 100A is explained with reference to FIG. 1. When the substrate processing apparatus 100A starts an operation, first, the transfer robot 222 takes out the substrate W from the wafer cassette placed on the front loader 220. Subsequently, the substrate W held by the transfer robot 222 is passed to the transporter 102. Subsequently, the transporter 102 transfers the substrate W to the fourth transfer position TP4.

Subsequently, the top ring 331 of the first polishing device 302A holds the substrate W placed in the fourth transfer position TP4 and transfers to substrate W to a position opposed to the polishing pad 310. Subsequently, the top ring 331 presses the substrate W against the polishing surface of the polishing pad 310 and the substrate W is polished. Note that, at the time of the polishing, the polishing liquid is supplied from the polishing liquid supply nozzle 332 to the polishing surface of the polishing pad 310. Subsequently, the top ring 331 moves in the upward direction. Consequently, the polishing pad 310 separates from the substrate W and the polishing by the first polishing device 302A ends. When the polishing by the first polishing device 302A ends, the top ring 331 returns the substrate W to the fourth transfer position TP4. Subsequently, the transporter 102 moves the substrate W placed in the fourth transfer position TP4 to the fifth transfer position TP5.

Subsequently, the top ring 331 of the second polishing device 302B holds the substrate W placed in the fifth transfer position TP5 and transfers the substrate W to the position opposed to the polishing pad 310. Subsequently, the top ring 331 presses the substrate W against the polishing surface of the polishing pad 310 and the substrate W is polished. Subsequently, the top ring 331 moves in the upward direction. Consequently, the polishing pad 310 separates from the substrate W and the polishing by the second polishing device 302B ends. When the polishing by the second polishing device 302B ends, the top ring 331 returns the substrate W to the fifth transfer position TP5. In this way, in the substrate processing apparatus 100A, the substrate W is polished in two stages. Therefore, the polishing surface (the treatment surface) of the substrate W is flatter than when the substrate W is polished only in one stage.

Subsequently, the substrate W is transferred to the buff cleaning device 420A and is held by the buff table 422 (see FIG. 3). Subsequently, the chemical liquid nozzle 480 supplies the cleaning chemical liquid to the substrate W. Subsequently, the buff pad 424 comes into contact with the substrate W and the buff head 426 and the buff table 422 rotate. At this time, the buff head 426 performs a horizontal motion in the plane of the substrate W. Consequently, buff cleaning for the substrate W is performed. Subsequently, while the pure water nozzle 472 is supplying the pure water to the substrate W, the buff pad 424 comes into contact with the substrate W and the buff head 426 and the buff table 422 rotate. Consequently, the cleaning chemical liquid is washed away from the substrate W. Subsequently, the buff head 426 moves in the upward direction. Consequently, the buff head 426 separates from the substrate W. The buff cleaning by the buff cleaning device 420A ends. Note that the substrate W may be further cleaned by the pure water after the buff cleaning according to necessity.

Subsequently, the substrate W is transferred to the coating device 500 and held by the table 502 (see FIG. 4). Subsequently, in a state in which the table 502 is rotating, the rinse water nozzle 506 supplies the rinse water to the substrate W. At this time, degassed pure water or pure water added with CO₂ bubbles is used as the rinse water. Consequently, the metal region of the substrate W is further suppressed from being oxidized than when normal water is used as the rinse water. Subsequently, the supply of the rinse water from the rinse water nozzle 506 is stopped, the table 502 further rotates, and the substrate W is spun and dried. Subsequently, in a state in which the table 502 is rotating, the nozzle 512 supplies the silane coupling agent or the resin protective film agent to the substrate W. Consequently, the silane coupling agent or the resin protective film agent is applied to the substrate W. Thereafter, the supply of the silane coupling agent or the resin protective film agent is stopped and the rotation of the table 502 is stopped.

Subsequently, the substrate W is transferred to the bake device 600 and stored in the load/unload cooling chamber 604 (see FIG. 6). Subsequently, the shutter 610 opens and the substrate W is transferred from the load/unload cooling chamber 604 to the heater chamber 602. Thereafter, as an example, the substrate W is heated at 100±30 degrees for one minute to ten minutes. Consequently, the silane coupling agent or the resin protective film agent and the surface of the substrate W are combined by chemical reaction and a protective layer formed from the silane coupling agent or the resin protective film agent is formed on the surface of the substrate W. Subsequently, the substrate W is returned to the load/unload cooling chamber 604 and cooled. Thereafter, the cooled substrate W is transferred to the drying device 404. Note that, according to necessity, the substrate W may be further cleaned before being transferred to the drying device 404.

The substrate W transferred to the drying device 404 is dried by the drying device 404. The dried substrate W is returned to the wafer cassette placed on the front loader 220. The example of the operation of the substrate processing apparatus 100A is as explained above.

As explained above, the substrate processing apparatus 100A can form the protective layer on the surface of the polished semiconductor substrate W. The metal region of the substrate W is protected from the oxygen in the air and is not oxidized. That is, the substrate processing apparatus 100A can protect the surface of the polished metal region of the substrate W from oxidization.

The substrate processing apparatus 100A can protect the surfaces of the metal region and the insulation region of the substrate W from particles and the like with the protective layer in a process from a CMP process (a polishing process) to substrate bonding.

It is known that a layer formed using the silane coupling agent or the resin protective film agent has a bonding function. Therefore, two substrates W on which protective layers are formed are bonded by being superimposed. That is, the substrate W on which the protective layer is formed by the substrate processing apparatus 100A can be bonded to another substrate W without being subjected to the surface activation treatment and the hydrophilic treatment necessary to bond the substrates W in the related art.

Note that annealing for heating the two substrates W to approximately 400° C. may be applied to the bonded substrates W. When the annealing is applied to the two substrates W, a space between metal regions of the two substrates W is closed and the metal regions of the two substrates W are satisfactorily bonded.

Further, in the substrate processing apparatus 100A, the control device 900A is configured to control the second polishing device 302B, the coating device 500, and the bake device 600 such that a time from end time of the polishing by the second polishing device 302B to start time of the formation of the protective layer is ten minutes or less. Note that the end time of the polishing by the second polishing device 302B is time when the polishing pad 310 separates from the substrate W. The start time of the formation of the protective layer is time when the silane coupling agent or the resin protective film agent comes into contact with the substrate W.

Since the substrate processing apparatus 100A includes the control device 900A explained above, the formation of the protective layer is started within ten minutes from the end time of the polishing. Consequently, the protective layer is formed before the metal region of the substrate W is oxidized. That is, the substrate processing apparatus 100A can form the protective layer before the metal region of the polished substrate W is oxidized.

<Substrate Processing Apparatus 100B>

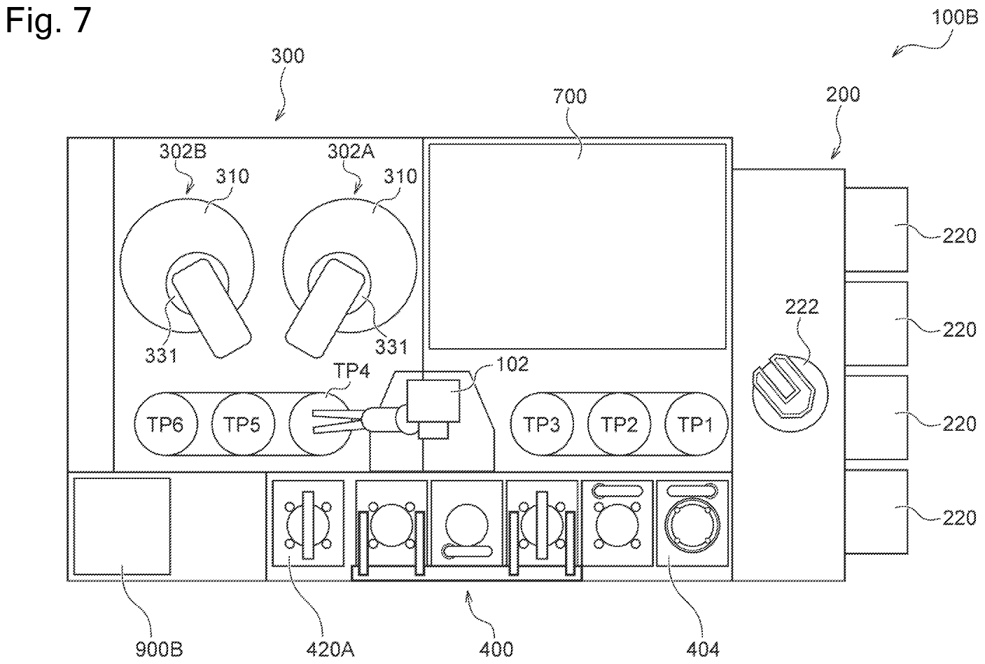

FIG. 7 is a plan view showing an overall configuration of a substrate processing apparatus 100B according to another embodiment of the present disclosure. Referring to FIG. 7, the substrate processing apparatus 100B includes the load/unload module 200, the polishing module 300, the cleaning module 400, and a protective layer forming device 700. Further the substrate processing apparatus 100B includes a control device 900B for controlling operations of the load/unload module 200, the polishing module 300, the cleaning module 400, and the protective layer forming device 700.

<Protective Layer Forming Device 700>

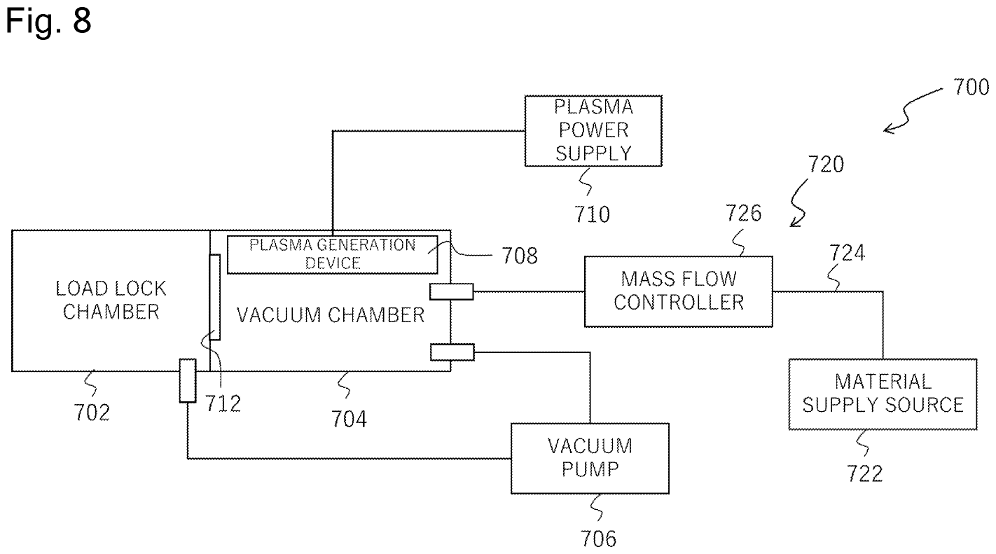

FIG. 8 is a block diagram schematically showing the protective layer forming device 700. Referring to FIG. 8, the protective layer forming device 700 includes a load lock chamber 702, a vacuum chamber 704, a vacuum pump 706, a silane coupling agent supply device 720, a plasma generation device 708, a plasma power supply 710, and a shutter 712.

The load lock chamber 702 and the vacuum chamber 704 are configured to be able to store the substrate W. The load lock chamber 702 and the vacuum chamber 704 are connected to each other via the shutter 712. The vacuum pump 706 is configured to be able to evacuate gas on the inside of the load lock chamber 702 and the inside of the vacuum chamber 704.

The silane coupling agent supply device 720 includes a pipe 724 that connects a material supply source 722 and the vacuum chamber 704 and a mass flow controller 726 for adjusting a flow rate of fluid flowing in the pipe 724. The material supply source 722 is configured to supply the silane coupling agent in a gas state to the vacuum chamber 704 via the pipe 724. Since the silane coupling agent supply device 720 has such a configuration, the silane coupling agent in the gas state can be supplied to the inside of the vacuum chamber 704 at a predetermined flow rate. The plasma generation device 708 is configured to be able to generate plasma on the inside of the vacuum chamber 704 with a known method using electric power supplied from the plasma power supply 710.

<Operation of the Substrate Processing Apparatus 100B>

Subsequently, an example of an operation of the substrate processing apparatus 100B is explained with reference to FIG. 7. When the substrate processing apparatus 100B starts the operation, first, the transfer robot 222 takes out the substrate W from the wafer cassette placed on the front loader 220. Subsequently, the substrate W held by the transfer robot 222 is passed to the transporter 102. Subsequently, the transporter 102 transfers the substrate W to the fourth transfer position TP4.

Subsequently, the top ring 331 of the first polishing device 302A holds the substrate W placed in the fourth transfer position TP4 and transfers the substrate W to the position opposed to the polishing pad 310. Subsequently, the top ring 331 presses the substrate W against the polishing surface of the polishing pad 310 and the substrate W is polished. Note that, at the time of the polishing, the polishing liquid is supplied from the polishing liquid supply nozzle 332 to the polishing surface of the polishing pad 310. Subsequently, the top ring 331 moves in the upward direction. Consequently, the polishing pad 310 separates from the substrate W and the polishing by the first polishing device 302A ends. When the polishing by the first polishing device 302A ends, the top ring 331 returns the substrate W to the fourth transfer position TP4. Subsequently, the transporter 102 moves the substrate W placed in the fourth transfer position TP4 to the fifth transfer position TP5.

Subsequently, the top ring 331 of the second polishing device 302B holds the substrate W placed in the fifth transfer position TP5 and transfers the substrate W to the position opposed to the polishing pad 310. Subsequently, the top ring 331 presses the substrate W against the polishing surface of the polishing pad 310 and the substrate W is polished. Subsequently, the top ring 331 moves in the upward direction. Consequently, the polishing pad 310 separates from the substrate W and the polishing by the second polishing device 302B ends. When the polishing by the second polishing device 302B ends, the top ring 331 returns the substrate W to the fifth transfer position TR5.

Subsequently, the substrate W is transferred to the buff cleaning device 420A and buff cleaning for the substrate W is performed. Thereafter, the substrate W is further cleaned in the cleaning module 400 according to necessity. Subsequently, the cleaned substrate W is transferred to the drying device 404. The substrate W is dried by the drying device 404.

Subsequently, the dried substrate W is transferred to the protective layer forming device 700. First, the substrate W transferred to the protective layer forming device 700 is stored in the load lock chamber 702 (see FIG. 8). Subsequently, the vacuum pump 706 sucks gas on the inside of the load lock chamber 702 and evacuation into the load lock chamber 702 is started. Subsequently, the shutter 712 opens and the substrate W moves from the load lock chamber 702 to the vacuum chamber 704. Note that the vacuum chamber 704 is evacuated in advance. Subsequently, gas for plasma generation is supplied to the inside of the vacuum chamber 704. The plasma generation device 708 generates plasma using the gas for plasma generation. The surface of the substrate W is subjected to plasma treatment by the plasma. Note that, as an example, the gas for plasma generation is any one of argon, nitrogen, air, water vapor, and carbon dioxide or gas obtained by mixing two or more of these gasses.

When the plasma treatment on the substrate W ends, the silane coupling agent supply device 720 supplies the silane coupling agent in the gas state to the inside of the vacuum chamber 704. Consequently, the substrate W is exposed to the silane coupling agent and a protective layer is formed on the surface of the substrate W.

Thereafter, the substrate W on which the protective layer is formed is returned to the wafer cassette placed on the front loader 220. The example of the operation of the substrate processing apparatus 100B is as explained above.

As explained above, like the substrate processing apparatus 100A, the substrate processing apparatus 100B can form the protective layer on the surface of the polished semiconductor substrate W. That is, the substrate processing apparatus 100B can protect the surface of the metal region of the polished substrate W from oxidation.

Further, in the substrate processing apparatus 100B, the control device 900B is configured to control the second polishing device 302B and the protective layer forming device 700 such that a time from end time of the polishing by the second polishing device 302B to start time of the formation of the protective layer is ten minutes or less. Note that the end time of the polishing by the second polishing device 302B is time when the polishing pad 310 separates from the substrate W. The start time of the formation of the protective layer is time when evacuation into the load lock chamber 702 in which the substrate W is stored is started.

Since the control device 900B is configured as explained above, like the substrate processing apparatus 100A, the substrate processing apparatus 100B can form the protective layer before the metal region of the polished substrate W is oxidized.

<Substrate Processing Apparatus 100C>

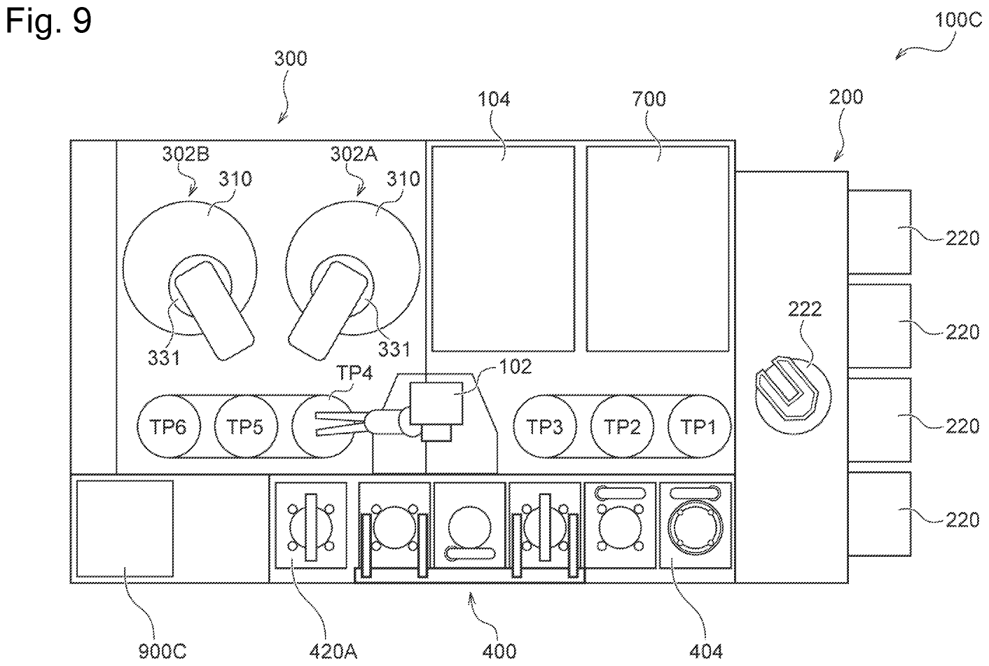

FIG. 9 is a plan view showing an overall configuration of a substrate processing apparatus 100C according to another embodiment of the present disclosure. Referring to FIG. 9, the substrate processing apparatus 100C includes the load/unload module 200, the polishing module 300, the cleaning module 400, the protective layer forming device 700, and a plating device 104. Further, the substrate processing apparatus 100C includes a control device 900C for controlling operations of the load/unload module 200, the polishing module 300, the cleaning module 400, the protective layer forming device 700, and the plating device 104. The plating device 104 is configured to apply plating to the surface of the substrate W with a known method.

The substrate processing apparatus 100C is different from the substrate processing apparatus 100B in that the substrate processing apparatus 100C includes the plating device 104. The substrate processing apparatus 100C can form a metal region on the surface of the substrate W using the plating device 104.

<Substrate Processing Apparatus 100D>

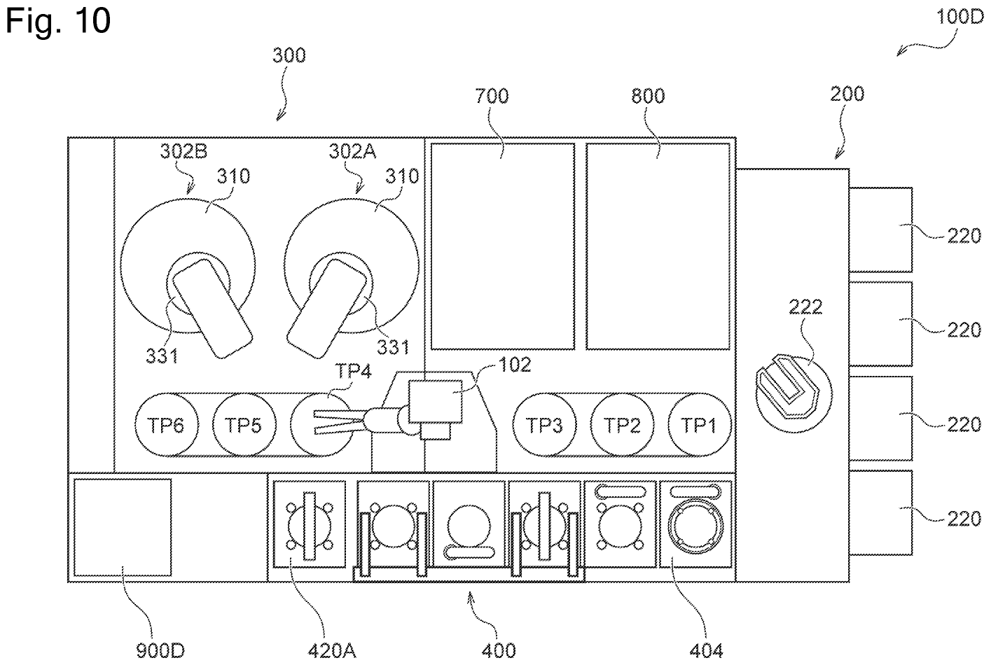

FIG. 10 is a plan view showing an overall configuration of a substrate processing apparatus 100D according to another embodiment of the present disclosure. Referring to FIG. 10, the substrate processing apparatus 100D includes the load/unload module 200, the polishing module 300, the cleaning module 400, the protective layer forming device 700, and a bonding device 800. Further the substrate processing apparatus 100D includes a control device 900D for controlling operations of the load/unload module 200, the polishing module 300, the cleaning module 400, the protective layer forming device 700, and the bonding device 800. The substrate processing apparatus 100D is different from the substrate processing apparatus 100B in that the substrate processing apparatus 100D includes the bonding device 800.

<Bonding Device 800>

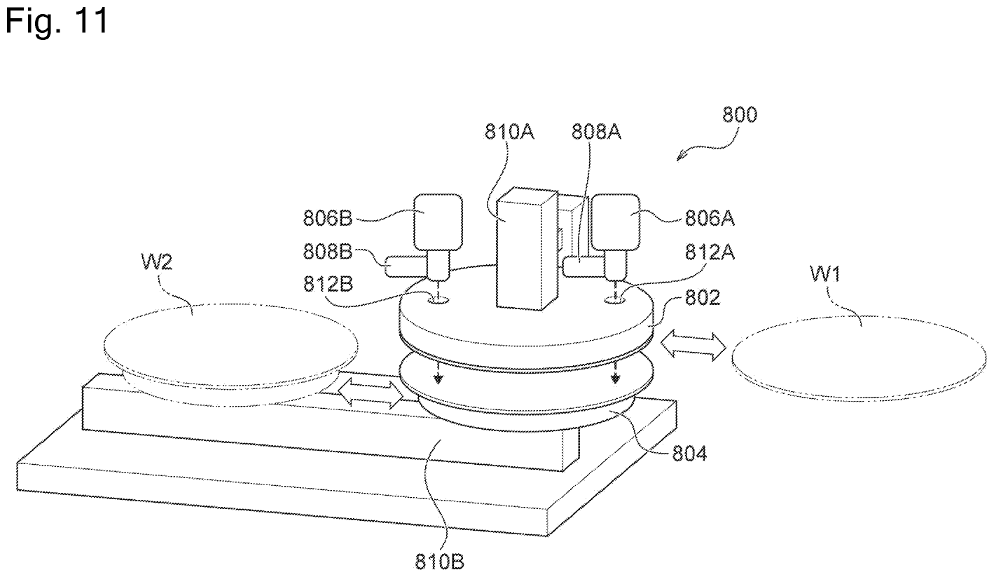

FIG. 11 is a perspective view schematically showing the bonding device 800. Referring to FIG. 11, the bonding device 800 includes an upper chuck 802, a lower chuck 804, two cameras 806A and 806B, two light sources 808A and 808B, and moving devices 810A and 810B. The upper chuck 802 is configured to be able to grip a first substrate W1. On the other hand, the lower chuck 804 is configured to be able to grip a second substrate W2. The two cameras 806A and 806B are configured to be able to respectively image the first substrate W1 and the second substrate W2 from holes 812A and 812B formed in the upper chuck 802. The two light sources 808A and 808B respectively provide light necessary for the imaging to the cameras 806A and 806B. The moving device 810A is configured to be able to move the upper chuck 802. On the other hand, the moving device 810B is configured to be able to move the lower chuck 804.

Subsequently, an operation of the bonding device 800 is explained. First, the upper chuck 802 grips the first substrate W1 and the lower chuck 804 grips the second substrate W2. Subsequently, the moving devices 810A and 810B horizontally move the upper chuck 802 and the lower chuck 804 to positions where the two cameras 806A and 806B can image the first substrate W1 and the second substrate W2. Subsequently, the two cameras 806A and 806B image the first substrate W1 and the second substrate W2. At this time, a positional relation between the first substrate W1 and the second substrate W2 can be recognized from alignment marks attached to the first substrate W1 and the second substrate W1. Subsequently, the moving devices 810A and 810B horizontally move the upper chuck 802 and the lower chuck 804 such that the alignment mark of the first substrate W1 and the alignment mark of the second substrate W2 coincide. Subsequently, the upper chuck 802 moves in a direction approaching the lower chuck 804. Consequently, the first substrate W1 comes into contact with and is bonded to the second substrate W2. In this way, the bonding device 800 can bond the first substrate W1 and the second substrate W2. In other words, the substrate processing apparatus 100D can bond two substrates W.

[Notes]

A part or all of the embodiments explained above can be described as indicated by the following notes but are not limited to the following description.

(Note 1)

A substrate processing apparatus according to Note 1 includes: a polishing device for polishing a semiconductor substrate; a protective layer forming device for forming a protective layer on a surface of the substrate using a silane coupling agent or a resin protective film agent; and a control device. The control device controls the polishing device and the protective layer forming device such that the protective layer forming device forms the protective layer on the substrate after the polishing device finishes polishing the substrate.

The substrate processing apparatus according to Note 1 forms the protective layer on the surface of the polished semiconductor substrate. Consequently, a metal region of the substrate is protected from the oxygen in the air and is not oxidized. That is, the substrate processing apparatus can protect the surface of the metal region of the polished substrate from oxidation. Further, the surface of the substrate is protected by the protective layer and adhesion of cutting chips and particles to the surface of the substrate is suppressed. The protective layer formed using a silane coupling agent or a resin protective film agent has a bonding function. Therefore, the substrate on which the protective layer is formed can be bonded to another substrate without being subjected to surface activation treatment and hydrophilic treatment necessary to bond substrates in the past.

(Note 2)

With a substrate processing apparatus according to Note 2, in the substrate processing apparatus described in Note 1, the protective layer forming device is configured to form the protective layer using the silane coupling agent.

(Note 3)

With a substrate processing apparatus according to Note 3, in the substrate processing apparatus described in Note 1, the protective layer forming device is configured to form the protective layer using the resin protective film agent.

(Note 4)

With a substrate processing apparatus according to Note 4, in the substrate processing apparatus described in Note 1, the control device controls the polishing device and the protective layer forming device such that a time from end time of the polishing by the polishing device to start time of the formation of the protective layer by the protective layer forming device is ten minutes or less.

In the substrate processing apparatus according to Note 4, the formation of the protective layer is started within ten minutes from the end time of the polishing. Consequently, the protective layer is formed before a metal region of the substrate is oxidized. That is, the substrate processing apparatus can form the protective layer before the metal region of the polished substrate is oxidized.

(Note 5)

With a substrate processing apparatus according to Note 5, in the substrate processing apparatus described in Note 4, the polishing device includes a polishing pad, and the end time of the polishing by the polishing device is time when the polishing pad separates from the substrate.

(Note 6)

With a substrate processing apparatus according to Note 6, in the substrate processing apparatus described in Note 1 or 4, the protective layer forming device includes: a coating device for applying the silane coupling agent or the resin protective film agent to the substrate; and a bake device for heating the substrate.

The substrate processing apparatus according to Note 6 can form the protective layer by applying the silane coupling agent or the resin protective film agent to the substrate and thereafter heating the substrate. That is, the substrate processing apparatus can form the protective layer in a simple process in which plasma treatment is not used.

(Note 7)

With a substrate processing apparatus according to Note 7, in the substrate processing apparatus described in Note 6, the coating device includes: a table for rotating and drying the substrate; a nozzle for supplying the silane coupling agent or the resin protective film agent to the substrate installed in the coating device; and an on-off valve for adjusting a flow rate of the silane coupling agent or the resin protective film agent supplied from the nozzle to the substrate, and the control device controls the on-off valve to cause the nozzle to supply the silane coupling agent or the resin protective film agent to the substrate after a center of the substrate is dried and before an outer circumferential portion of the substrate is dried.

The substrate processing apparatus according to Note 7 can further reduce a time in which the surface of the substrate touches the oxygen after the substrate is dried and can suppress formation of an oxide film on the surface of the metal region of the substrate.

(Note 8)

With a substrate processing apparatus according to Note 8, in the substrate processing apparatus described in Note 6, the coating device includes: a buff table for the substrate to be installed thereon; a buff pad for coming into contact with the substrate installed on the buff table and performing buff cleaning for the substrate; and a nozzle for supplying the silane coupling agent or the resin protective film agent to the substrate installed on the buff table.

In the substrate processing apparatus according to Note 8, the coating device can perform the buff cleaning. That is, in the substrate processing apparatus, the coating device functions as a buff cleaning device as well.

(Note 9)

With a substrate processing apparatus according to Note 9, in the substrate processing apparatus described in Note 6 citing Note 4, the start time of the formation of the protective layer is time when the silane coupling agent or the resin protective film agent comes into contact with the substrate.

(Note 10)

With a substrate processing apparatus according to Note 10, in the substrate processing apparatus described in Note 1 or 4, the protective layer forming device includes: a load lock chamber for storing the substrate; a vacuum chamber for storing the substrate, the vacuum chamber being connected to the load lock chamber via a shutter; a vacuum pump for evacuating gas on an inside of the load lock chamber and an inside of the vacuum chamber; a silane coupling agent supply device for supplying the silane coupling agent to the inside of the vacuum chamber; and a plasma generation device for generating plasma on the inside of the vacuum chamber.

The substrate processing apparatus according to Note 10 can supply the silane coupling agent to the inside of the vacuum chamber in a state in which the plasma is generated on the inside of the vacuum chamber in which the substrate is stored. Consequently, the protective layer is formed on the surface of the substrate. That is, the substrate processing apparatus can form the protective layer using the plasma treatment.

(Note 11)

With a substrate processing apparatus according to Note 11, in the substrate processing apparatus described in Note 10 citing Note 4, the start time of the formation of the protective layer is time when evacuation into the load lock chamber in which the substrate is stored is started.

(Note 12)

A substrate processing apparatus according to Note 12 further includes, in the substrate processing apparatus described in Note 1 or 2, a plating device for forming a metal region on the substrate.

The substrate processing apparatus according to Note 12 can form the metal region on the substrate.

(Note 13)

A substrate processing apparatus according to Note 13 further includes, in the substrate processing apparatus described in Note 1 or 2, a bonding device for bonding a pair of the substrates, the bonding device includes: an upper chuck for gripping a first substrate, which is one of the substrates; a lower chuck for gripping a second substrate, which is another one of the substrates; a camera for imaging the first substrate gripped by the upper chuck and the second substrate gripped by the lower chuck; and a moving device for moving at least one of the upper chuck and the lower chuck.

The substrate processing apparatus according to Note 13 can bond the two substrates.

(Note 14)

A protective layer forming method according to Note 14 includes: a first step of polishing a semiconductor substrate including a metal region; and a second step of forming a protective layer on a surface of the substrate using a silane coupling agent or a resin protective film agent after the first step.

The substrate processing apparatus according to Note 14 achieves the same effects as the effects of the substrate processing apparatus according to Note 1. That is, the protective layer forming method can protect the surface of the metal region of the polished substrate from oxidation. Further, the surface of the substrate is protected by the protective layer and adhesion of cutting chips and particles to the surface of the substrate is suppressed. The substrate on which the protective layer is formed by the method can be bonded to another substrate without being subjected to surface activation treatment and hydrophilic treatment necessary to bond substrates in the past.

The embodiments of the present invention and the modifications relating to the embodiments are explained above. However, it goes without saying that the examples explained above are examples for facilitating understanding of the present invention and do not limit the present invention. The present invention can be changed and improved in a range not departing from the gist of the present invention. Equivalents of the present invention are included in the present invention. The components described in the claims and the specification can be optionally combined or can be omitted in a range in which at least a part of the problems described above can be solved or a range in which at least a part of the effects can be achieved.

### REFERENCE SIGNS LIST

100A, 100B, 100C, 100D: substrate processing apparatus
104: plating device
302A: first polishing device (polishing device)
302B: second polishing device (polishing device)
310: polishing pad
420A, 420B: buff cleaning device
422: buff table
424: buff pad
496: nozzle
500: coating device
600: bake device
700: protective layer forming device
702: load lock chamber
704: vacuum chamber
706: vacuum pump
708: plasma generation device
720: silane coupling agent supply device
800: bonding device
802: upper chuck
804: lower chuck
806A, 806B: camera
810A, 810B: moving device
900A, 900B, 900C, 900D: control device
W: substrate
W1: first substrate
W2: second substrate

What is claimed is:

1. A substrate processing apparatus comprising:
a polishing device for polishing a semiconductor substrate;
a protective layer forming device for forming a protective layer on a surface of the substrate using a silane coupling agent or a resin protective film agent; and
a control device, wherein
the control device controls the polishing device and the protective layer forming device such that the protective layer forming device forms the protective layer on the substrate after the polishing device finishes polishing the substrate.

2. The substrate processing apparatus according to claim 1, wherein the protective layer forming device is configured to form the protective layer using the silane coupling agent.

3. The substrate processing apparatus according to claim 1, wherein the protective layer forming device is configured to form the protective layer using the resin protective film agent.

4. The substrate processing apparatus according to claim 1, wherein the control device controls the polishing device and the protective layer forming device such that a time from end time of the polishing by the polishing device to start time of the formation of the protective layer by the protective layer forming device is ten minutes or less.

5. The substrate processing apparatus according to claim 4, wherein
the polishing device includes a polishing pad, and
the end time of the polishing by the polishing device is time when the polishing pad separates from the substrate.

6. The substrate processing apparatus according to claim 1, wherein the protective layer forming device includes:
a coating device for applying the silane coupling agent or the resin protective film agent to the substrate; and
a bake device for heating the substrate.

7. The substrate processing apparatus according to claim 6, wherein
the coating device includes:
a table for rotating and drying the substrate;
a nozzle for supplying the silane coupling agent or the resin protective film agent to the substrate installed in the coating device; and
an on-off valve for adjusting a flow rate of the silane coupling agent or the resin protective film agent supplied from the nozzle to the substrate, and
the control device controls the on-off valve to cause the nozzle to supply the silane coupling agent or the resin protective film agent to the substrate after a center of the substrate is dried and before an outer circumferential portion of the substrate is dried.

8. The substrate processing apparatus according to claim 6, wherein the coating device includes:
a buff table for the substrate to be installed thereon;
a buff pad for coming into contact with the substrate installed on the buff table and performing buff cleaning for the substrate; and
a nozzle for supplying the silane coupling agent or the resin protective film agent to the substrate installed on the buff table.

9. The substrate processing apparatus according to claim 6, wherein the start time of the formation of the protective layer is time when the silane coupling agent or the resin protective film agent comes into contact with the substrate.

10. The substrate processing apparatus according to claim 4, wherein the protective layer forming device includes:
a load lock chamber for storing the substrate;
a vacuum chamber for storing the substrate, the vacuum chamber being connected to the load lock chamber via a shutter;
a vacuum pump for evacuating gas on an inside of the load lock chamber and an inside of the vacuum chamber;
a silane coupling agent supply device for supplying the silane coupling agent to the inside of the vacuum chamber; and
a plasma generation device for generating plasma on the inside of the vacuum chamber.

11. The substrate processing apparatus according to claim 10, wherein the start time of the formation of the protective layer is time when evacuation into the load lock chamber in which the substrate is stored is started.

12. The substrate processing apparatus according to claim 1, further comprising a plating device for forming a metal region on the substrate.

13. The substrate processing apparatus according to claim 1, further comprising a bonding device for bonding a pair of the substrates, wherein
the bonding device includes:
an upper chuck for gripping a first substrate, which is one of the substrates;
a lower chuck for gripping a second substrate, which is another one of the substrates;
a camera for imaging the first substrate gripped by the upper chuck and the second substrate gripped by the lower chuck; and
a moving device for moving at least one of the upper chuck and the lower chuck.

14. A protective layer forming method comprising:
a first step of polishing a semiconductor substrate including a metal region; and
a second step of forming a protective layer on a surface of the substrate using a silane coupling agent or a resin protective film agent after the first step.
